(19) United States
(12) Patent Application Publication
(10) Pub. No.: US 2024/0250225 A1
(43) Pub. Date: Jul. 25, 2024

(54) DISPLAY DEVICE INCLUDING LENSES AND METHOD OF MANUFACTURING THE SAME

(71) Applicant: SAMSUNG DISPLAY CO., LTD., YONGIN-SI (KR)

(72) Inventors: Jeong Woo Park, Yongin-si (KR); Beom Shik Kim, Yongin-si (KR); Rang Kyun Mok, Yongin-si (KR); Byeong Hee Won, Yongin-si (KR); Young Sang Ha, Yongin-si (KR)

(21) Appl. No.: 18/518,909

(22) Filed: Nov. 24, 2023

(30) Foreign Application Priority Data
Jan. 19, 2023 (KR) 10-2023-0008276

(51) Int. Cl. H01L 33/58; H01L 25/075; H01L 27/15; H01L 33/44

(52) U.S. Cl. CPC H01L 33/58; H01L 25/0753; H01L 27/156; H01L 33/44; H01L 2933/0025

(57) ABSTRACT

A display device includes a display panel including sub-pixels arranged in a first direction and a second direction perpendicular to the first direction, and including light emitting surfaces in a third direction perpendicular to the first direction and the second direction, and lenses that overlap the sub-pixels in the third direction and to have a long side having an angle greater than 0 degree with respect to the second direction. A first lens includes a first curved surface and a first side surface connected to one edge of the first curved surface. A second lens includes a second curved surface and a second side surface connected to one edge of the second curved surface. The first lens and the second lens share a common lower surface. A flat surface connects the first side surface and the second side surface and extends parallel to the common lower surface.

This application claims priority under 35 U.S.C. § 119 to Korean Patent Application No. 10-2023-0008276, filed on Jan. 19, 2023, the content of which is herein incorporated by reference in its entirety.

### TECHNICAL FIELD

The present disclosure relates to a display device and, more specifically, to a display device including lenses and a method of manufacturing the same.

### DISCUSSION

Display devices are an important component of modern electronic devices. Popular forms of display devices include liquid crystal display (LCD) devices and organic light emitting diode (OLED) display devices.

Some display devices are capable of permitting a viewer to perceive a three-dimensional (3D) image. One example of such a 3D display is a stereoscopic image display device that provides different images to a left eye and a right eye of the viewer so that the viewer may view the stereoscopic image by binocular parallax between the left eye and the right eye. Such approaches have often required the use of 3D glasses to block a left-eye image from reaching the right eye of a viewer and to block a right-eye image from reaching the left eye of the viewer.

Some display devices utilize an autostereoscopic method in which stereoscopic glasses are not worn. An Example of the autostereoscopic method includes a lenticular method for separating left and right eye images using a cylindrical lens array, and a barrier method for separating left and right eye images using a barrier.

### SUMMARY

A display device includes a display panel including sub-pixels arranged in a first direction and a second direction perpendicular to the first direction. The sub pixels each include a light emitting surface facing a third direction that is perpendicular to the first direction and the second direction. Lenses at least partially overlap the sub-pixels in the third direction and have a long side having an angle greater than 0 degree with respect to the second direction. The lenses include a first lens including a first curved surface that is curved with respect to the third direction and a first side surface that is connected to one edge of the first curved surface, the first side surface being inclined at a first angle with respect to the third direction. A second lens includes a second curved surface that is curved in the third direction and a second side surface connected to one edge of the second curved surface, the second side surface being inclined at a second angle with respect to the third direction. The first lens and the second lens share a common lower surface. A flat surface connects the first side surface and the second side surface to each other and extends parallel to the common lower surface, A magnitude of each of the first angle and the second angle is greater than 0 degrees.

The magnitude of the first angle may be equal to the magnitude of the second angle, and a sign of the first angle may be opposite to a sign of the second angle.

A length in the first direction of the flat surface may be longer than a length in the first direction of any one of the sub-pixels, and a length in the first direction of the first curved surface or the second curved surface may be longer than the length in the first direction of the flat surface.

A length in the first direction of the flat surface may be at least two times longer than a length in the first direction of any one of the sub-pixels.

Each magnitude of the first angle and the second angle may be less than 3 degrees.

The first curved surface and the second curved surface may be convex in the third direction.

The first curved surface and the second curved surface may be concave in the third direction.

The display device may further include a light blocker contacting the first side surface, the second side surface, and the flat surface.

A length of the third direction of the light blocker may be longer than 6 μm.

The display panel may further include align marks at least partially overlapping the flat surface.

A method of manufacturing a display device includes preparing a display panel including a plurality of sub-pixels. A lens array is positioned on the display panel. The lens array includes a first lens including a first curved surface and a first side surface connected to one edge of the first curved surface, a second lens including a second curved surface and a second side surface connected to one edge of the second curved surface, a common lower surface of the first lens and the second lens, and a flat surface connecting the first side surface and the second side surface and extending parallel to the common lower surface. The lens array and the display panel are aligned to one another using some of the sub-pixels observed through the flat surface.

In the aligning, the plurality of sub-pixels may be in a non-emission state.

The method may further include forming a light blocker on the flat surface after the lens array and the display panel are aligned.

A depth of the light blocker may be greater than 6 μm.

A width of the flat surface may be greater than a width of any one of the sub-pixels.

A method of manufacturing a display device includes preparing a display panel including a plurality of sub-pixels and a plurality of alignment marks. A lens array is positioned on the display panel. The lens array includes a first lens including a first curved surface and a first side surface connected to one edge of the first curved surface. A second lens includes a second curved surface and a second side surface connected to one edge of the second curved surface. The first lens and the second lens share a common lower surface. A flat surface connects the first side surface and the second side surface to one another and extends parallel to the common lower surface. The lens array and the display panel are aligned to one another using the alignment marks observed through the flat surface.

In the aligning, the plurality of sub-pixels may be in a non-emission state.

The method may further include forming a light blocker on the flat surface after the lens array and the display panel are aligned.

A depth of the light blocker may be greater than 6 μm.

A width of the flat surface may be greater than a width of any one of the sub-pixels.

### BRIEF DESCRIPTION OF THE DRAWINGS

The above and other features of the disclosure will become more apparent by describing in further detail embodiments thereof with reference to the accompanying drawings, in which:

FIG. 1 is a diagram illustrating a lens array type of stereoscopic image display device;

FIG. 2 is a diagram illustrating a relationship between a lens array and a display panel according to an embodiment of the disclosure;

FIG. 3 is a diagram illustrating shapes of viewed sub-pixels when the lens array of FIG. 2 is applied;

FIG. 4 is a diagram illustrating a relationship between a lens array and a display panel according to an embodiment of the disclosure;

FIG. 5 is a diagram illustrating a cross section of the lens array of FIG. 4;

FIG. 6 is a diagram illustrating shapes of the viewed sub-pixels when the lens array of

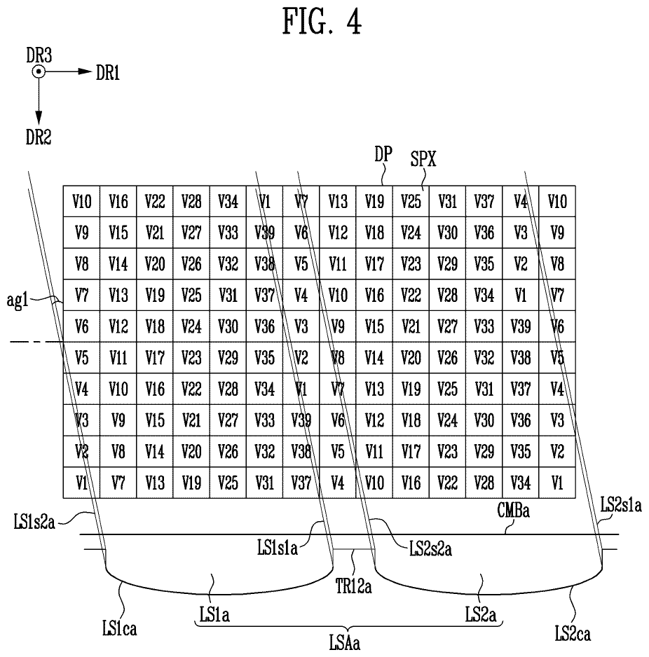

FIG. 4 is applied;

FIG. 7 is a diagram illustrating a display panel including align marks;

FIG. 8 is a diagram illustrating a case in which light blockers are formed in the lens array of FIG. 4;

FIG. 9 is a diagram illustrating a method of manufacturing a display device according to an embodiment of the disclosure; and

FIGS. 10 to 12 are diagrams illustrating a lens array according to embodiments of the disclosure.

### DETAILED DESCRIPTION OF THE EMBODIMENT

Hereinafter, various embodiments of the disclosure will be described in detail with reference to the accompanying drawings so that those skilled in the art may easily carry out the disclosure. The disclosure may be implemented in various different forms and is not necessarily limited to the embodiments described herein.

To the extent that elements are not described in detail herein, it may be assumed that these elements are at least similar to corresponding elements that are described elsewhere within the present specification. Same or similar elements are denoted by the same reference numerals throughout the specification and the drawings.

In addition, an expression “is the same” in the description may mean “is substantially the same”. For example, the expression “is the same” may be the same enough for those of ordinary skill to understand that it is the same. Other expressions may also be expressions in which “substantially” is to be inferred.

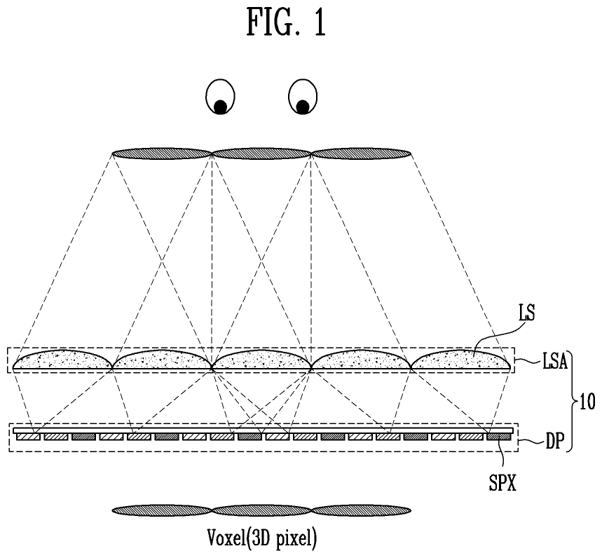

FIG. 1 is a diagram illustrating a lens array type of stereoscopic image display device.

Referring to FIG. 1, a display device 10 may include a display panel DP and a lens array LSA.

The display panel DP may include sub-pixels SPX that emit light to display an image. In an embodiment, each of the sub-pixels SPX may emit light of a first color (for example, red), light of a second color (for example, green), and light of a third color (for example, blue). However, this is an example, and a color of light emitted from the sub-pixels SPX is not necessarily limited thereto, and light of various colors for full-color implementation may be output. The display panel DP may include an organic light emitting display panel, a liquid crystal display panel, a quantum dot display panel, and the like.

The lens array LSA may include lenses LS disposed on the display panel DP and refracting light incident from the sub-pixels SPX. For example, the lens array LSA may be implemented as a lenticular lens array, a micro lens array, and the like.

A light field display is a 3D display device implementing a stereoscopic image by forming a light field expressed as a vector distribution (intensity, direction) of light on a space using a flat panel display and an optical element (for example, the lens array LSA). The light field display is a display technology that is expected to be used in various applications through convergence with augmented reality (AR) technology and the like, because the light field display may implement more natural a stereoscopic image by enabling viewing of a depth, a side, and the like of an object.

The light field may be implemented in a various methods. For example, the light field may be formed in a method of creating a light field of various directions using a plurality of projectors, a method of controlling a direction of light using a diffraction grating, a method of controlling the direction and an intensity (luminance) of light according to a combination of each pixel using two or more panels, a method of controlling the direction of light using a pinhole or a barrier, a method of controlling a refraction direction of light through the lens array, and the like.

In an embodiment, as shown in FIG. 1, the lens array type of stereoscopic image display device 10 may display a stereoscopic image (3D image) by forming the aforementioned light field.

A series of sub-pixels SPX may be allocated to each lens LS, and light emitted from each of the sub-pixels SPX may be refracted by the lens LS, may proceed only in a specific direction, and thus may form the light field expressed as an intensity and a direction of light. When a viewer looks at the display device 10 within the light field formed as described above, the viewer may feel a three-dimensional effect of a corresponding image.

Image information according to a viewer's viewpoint in the light field may be defined and processed in a voxel unit. A voxel may be understood as graphic information defining a predetermined point (or pixel) within three-dimensional space.

For example, a resolution of a two-dimensional image may be determined by the number of pixels (for example, density) of the same area. For example, when the number of pixels increases for the same area, the resolution may increase. For example, a display panel DP having a high pixel density may be used for displaying a high-resolution image. Similarly, when the number of voxels at the same viewpoint through the lens array LSA increases, the resolution of the stereoscopic image may increase.

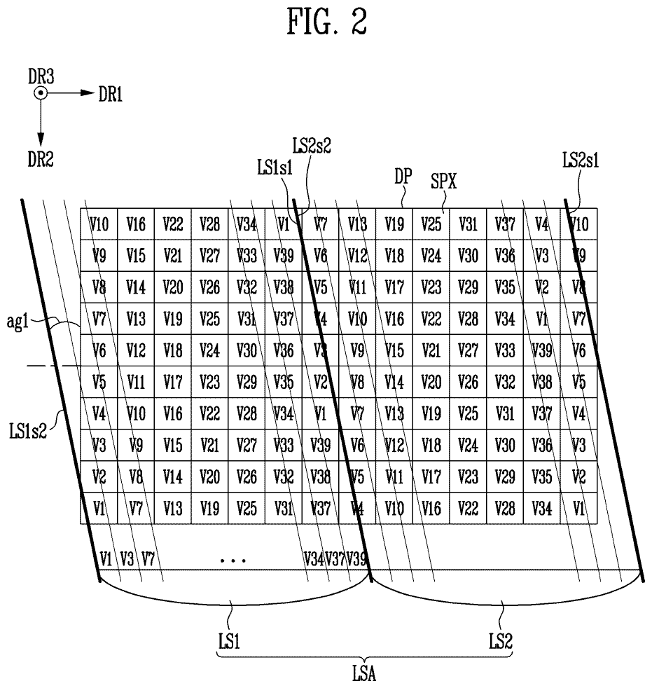

FIG. 2 is a diagram illustrating a relationship between a lens array and a display panel according to an embodiment of the disclosure.

The display panel DP may include the sub-pixels SPX arranged in a first direction DR1 and a second direction DR2 perpendicular to the first direction DR1. The sub-pixels SPX may include light emitting surfaces in a third direction DR3 that is perpendicular to the first and second directions DR1 and DR2.

The lens array LSA may include lenses LS1, LS2, . . . . The lenses LS1, LS2, . . .may at least partially overlap the sub-pixels SPX in the third direction DR3. The lenses LS1, LS2, . . . may be arranged to have a long side having an angle ag1 greater than 0 degrees with respect to the second direction DR2. For example, the lenses LS1, LS2, . . . may be lenticular lenses. For example, a first lens LS1 may include a first long side LS1s1 and a second long side LS1s2 that are parallel to each other. In addition, the second lens LS2 may include a first long side LS2s1 and a second long side LS2s2 that are parallel to each other. The lenses LS1, LS2, . . . may be arranged in the first direction DR1.

A lower surface (a surface facing the sub-pixels) of each of the lenses LS1, LS2, . . . may be partitioned into a plurality of viewpoint areas V1 to V39. The plurality of viewpoint areas V1 to V39 might not be physically partitioned, but may be virtual areas, and may be various defined by the resolution of the display panel DP, a standard of the lenses LS1, LS2, . . . , the number of viewpoints to be provided to a user, and the like. Each of the lenses LS1, LS2, . . . may distribute images corresponding to the respective viewpoint areas V1 to V39 in different directions (different viewpoints), and thus the user may view a multi-view image where the image changes according to a position.

The sub-pixels SPX may overlap one or more of the plurality of viewpoint areas V1 to V39. In FIG. 2, main viewpoint areas V1 to V39 corresponding to the sub-pixels are respectively marked on the sub-pixels SPX. Sub-pixels SPX corresponding to the same viewpoint area may display an image for the same viewpoint. For example, since 39 viewpoint areas V1 to V39 exist in FIG. 2, the display panel DP may simultaneously display 39 images.

For example, the display device 10 may display the stereoscopic image by enabling sub-pixels SPX overlapping the viewpoint areas V1 to V20 to display a right eye image and the sub-pixels SPX overlapping the viewpoint areas V21 to V39 to display a right eye image. In this case, the user is to be positioned so that the left eye image is recognized by a left eye and the right eye image is recognized by a right eye.

The sub-pixels SPX may be disposed according to various structures such as RGB stripe, diamond PENTILE™, S-stripe, Real RGB, normal and PENTILE™. As used herein, the term PENTILE™ refers to a sub-pixel arrangement developed by SAMSUNG.

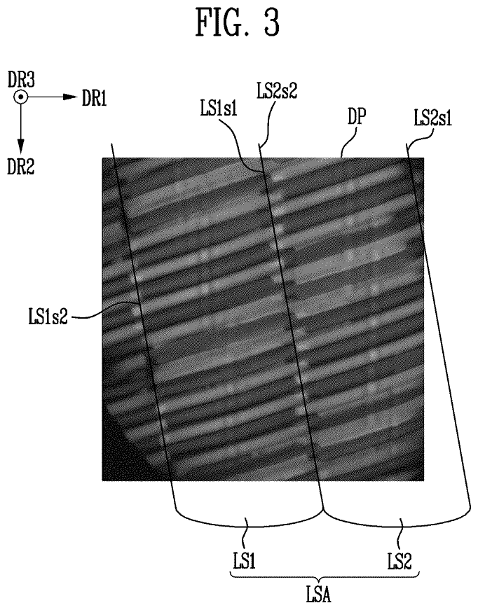

FIG. 3 is a diagram illustrating shapes of viewed sub-pixels when the lens array of FIG. 2 is applied.

Since all of the sub-pixels SPX are covered by the lens array LSA, the sub-pixels SPX are viewed as an elongated shape. Therefore, precise alignment of the lens array LSA and the display panel DP using the individual sub-pixels SPX cannot be performed. In addition, even though the display panel DP includes alignment marks, since the alignment marks also are viewed as an elongated shape by the lens array LSA, precise alignment by the alignment marks cannot be performed.

In order to precisely align the lens array LSA and the display panel DP, a stereoscopic image of a specific pattern viewed through the lens array LSA is checked by turning on the display panel DP (causing the sub-pixels SPX to be in an emission state). In this case, a takt time for lighting and checking the stereoscopic image of the display panel DP becomes long, and mass production of the display device 10 becomes unfavorable.

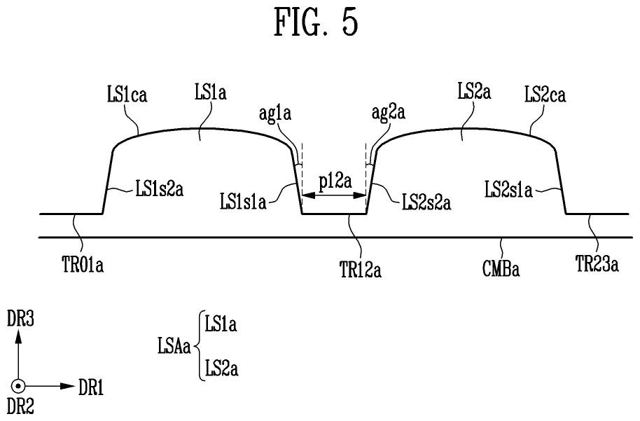

FIG. 4 is a diagram illustrating a relationship between a lens array and a display panel according to an embodiment of the disclosure. FIG. 5 is a diagram illustrating a cross section of the lens array of FIG. 4.

The display panel DP may include the sub-pixels SPX arranged in the first direction DR1 and the second direction DR2 perpendicular to the first direction DR1. The sub-pixels SPX may include the light emitting surfaces in the third direction DR3 perpendicular to the first direction DR1 and the second direction DR2.

The lens array LSAa may include lenses LS1a, LS2a, . . . . The lenses LS1a, LS2a, . . . may at least partially overlap the light emitting surfaces of the sub-pixels SPX in the third direction DR3. The lenses LS1a, LS2a, . . . may be arranged so that a long side has an angle ag1 with respect to the second direction DR2. For example, the lenses LS1a, LS2a, . . . may be lenticular lenses.

A first lens LS1a may include a first curved surface LS1ca curved in the third direction DR3, a first side surface LS1s1a connected to one edge of the first curved surface LS1ca, and a second side surface LS1s2a connected to another edge of the first curved surface LS1ca. The side surfaces LS1s1a and LS1s2a may have an angle ag1 with respect to the second direction DR2. The first curved surface LS1ca may be convex in the third direction DR3.

A second lens LS2a may include a second curved surface LS2ca curved in the third direction DR3, a first side surface LS2s1a connected to one edge of the second curved surface LS2ca, and a second side surface LS2s2a connected to another edge of the second curved surface LS2ca. The side surfaces LS2s1a and LS2s2a may have an angle ag1 with respect to the second direction DR2. The second curved surface LS2ca may be convex in the third direction DR3.

The first lens LS1a and the second lens LS2a may have a common lower surface CMBa. The lower surface CMBa may be a common component with respect to remaining lenses of the lens array LSAa. In this case, the lenses LS1a, LS2a, . . . of the lens array LSAa may be formed as one body. The lower surface CMBa may have a planar shape extending in the first direction DR1 and the second direction DR2. The lower surface CMBa may face the light emitting surfaces of the sub-pixels SPX of the display panel DP.

A flat surface TR12a may connect the first side surface LS1s1a of the first lens LS1a and the second side surface LS2s2a of the second lens LS2a, and may extend parallel to the lower surface CMBa. A length p12a of the first direction of the flat surface TR12a may be longer than a length of the first direction DR1 of any one of the sub-pixels SPX. Therefore, at least one sub-pixel may be fully viewed based on the first direction DR1 through the flat surface TR12a, and thus alignment using the sub-pixels SPX is possible in an alignment process of the lens array LSAa and the display panel DP.

In an embodiment, the length p12a of the first direction DR1 of the flat surface TR12a may be two or more times longer than the length of the first direction DR1 of any one of the sub-pixels SPX. When the sub-pixels SPX have a PENTILE™ structure, at least one pixel (e.g., a set of adjacent first color pixel, second color pixel, and third color pixel) may be fully viewed based on the first direction DR1 through the flat surface TR12a, and thus alignment using the pixels is possible in the alignment process of the lens array LSAa and the display panel DP.

In an embodiment, the length p12a of the first direction DR1 of the flat surface TR12a may be three or more times longer than the length of the first direction DR1 of any one of the sub-pixels SPX. When the sub-pixels SPX have a RGB stripe structure, at least one pixel (e.g., a set of adjacent first color pixel, second color pixel, and third color pixel) is fully viewed based on the first direction DR1 through the flat surface TR12a, and thus alignment using the pixels is possible in the alignment process of the lens array LSAa and the display panel DP.

Since the same description may be applied to flat surfaces TR01a, TR23a, . . . between other lenses, to the extent that an element has not been described in detail herein, it may be assumed that the element is at least similar to corresponding elements that have been described elsewhere within the present disclosure.

A length of the first direction DR1 of the first curved surface LS1ca or the second curved surface LS2ca may be longer than the length p12a of the first direction DR1 of the flat surface TR12a. Since the curved surfaces LS1ca, LS2ca, . . . of the lenses LS1a, LS2a, . . . serve as a main function for displaying a stereoscopic image, remaining sub-pixels SPX except for the sub-pixels SPX covered by the flat surfaces TR01a, TR12a, TR23a, . . . are covered.

The first side surfaces LS1s1a, LS2s1a, . . . of the lenses LS1a, LS2a, . . . may be inclined at an angle more than 0 degrees and less than 3 degrees with respect to the third direction DR3. Here, an inclined direction of a first angle ag1a may be a direction opposite to the first direction DR1 based on the third direction DR3.

In addition, the second side surfaces LS1s2a, LS2s2a, . . . of the lenses LS1a, LS2a, . . . may be inclined at an angle more than 0 degrees and less than 3 degrees with respect to the third direction DR3. Here, an inclined direction of a second angle ag2a may be the first direction DR1 based on the third direction DR3. For example, the direction in which the second side surfaces LS1s2a, LS2s2a, . . . are inclined with respect to the third direction DR3 may be an opposite to the direction in which the first side surfaces LS1s1a, LS2s1a, . . . are inclined with respect to the third direction DR3. For example, a magnitude of the first angle ag1a may be the same as that of the second angle ag2a, but a sign of the first angle ag1a may be different from that of the second angle ag2a. For example, when the second angle ag2a is expressed as (+) 2 degrees, the first angle ag1a may be expressed as (−) 2 degrees. In the following embodiments, to the extent that an element has not been described herein with respect to the first angle ag1a and the second angle ag2a, it may be assumed that the element is at least similar to corresponding elements that have been described elsewhere within the present disclosure.

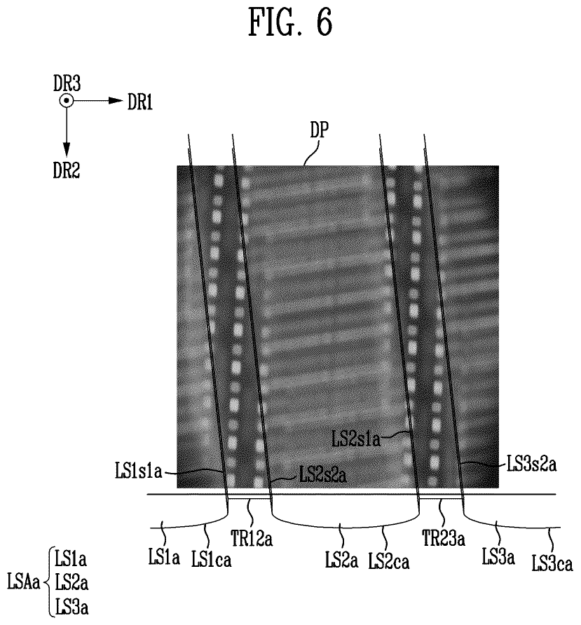

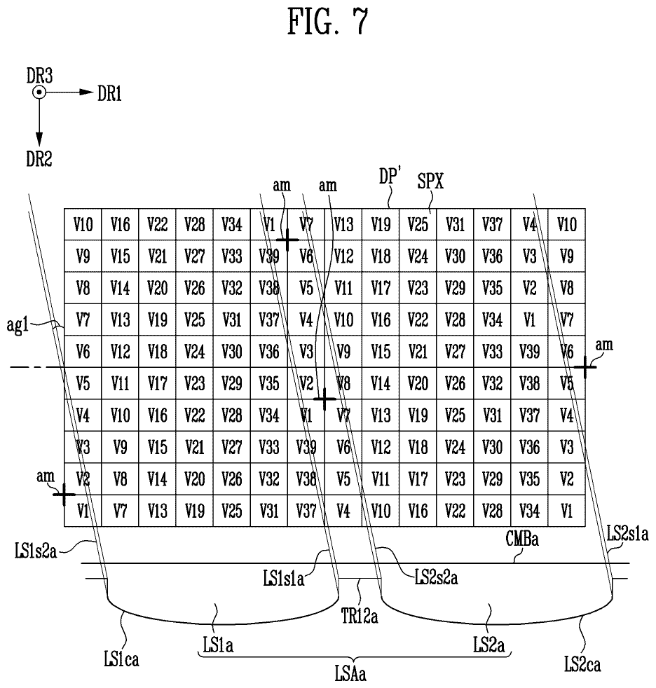

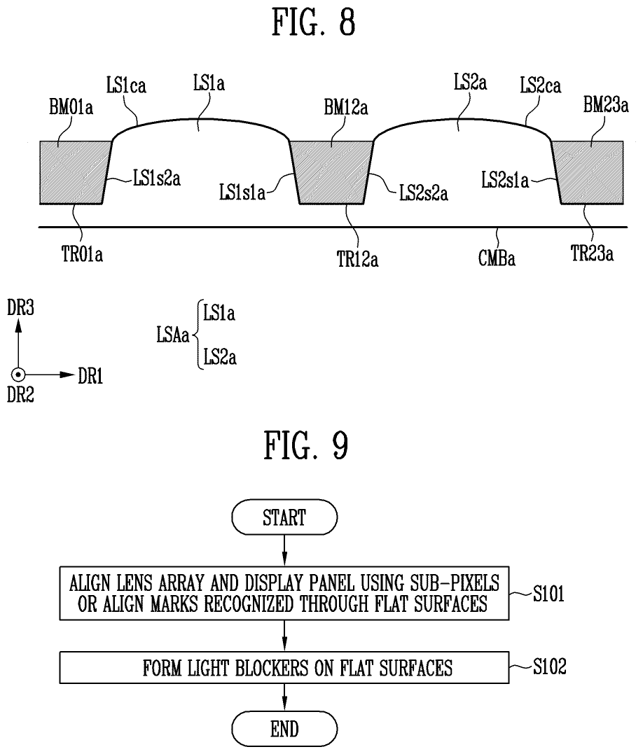

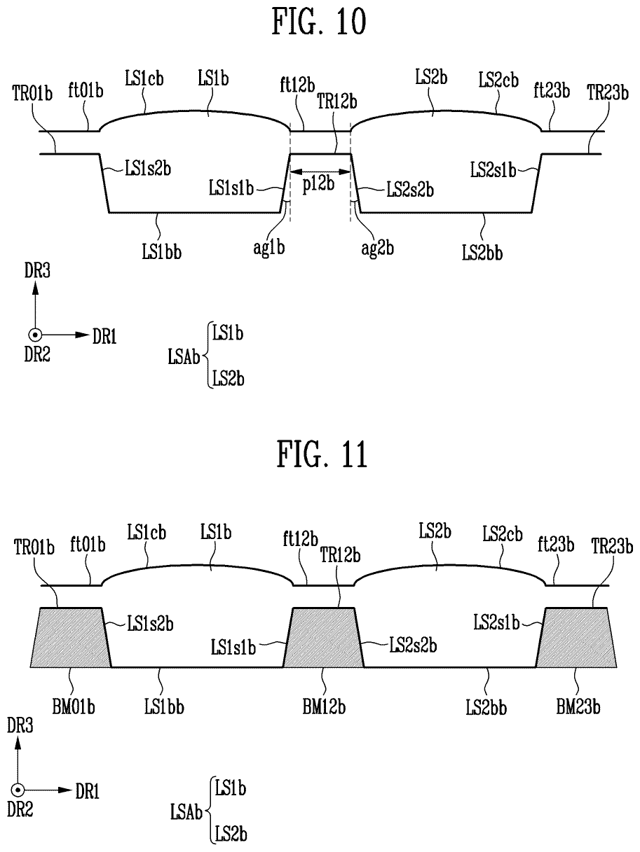

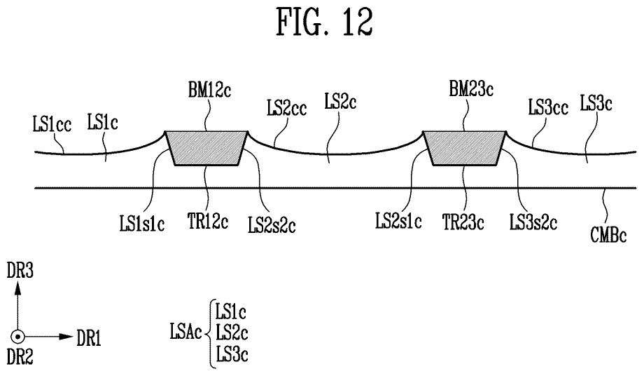

FIG. 6 is a diagram illustrating shapes of the viewed sub-pixels when the lens array of FIG. 4 is applied.

Referring to FIG. 6, an original shape of the sub-pixels SPX overlapping the flat surfaces TR12a, TR23a, . . . may be viewed. In addition, the sub-pixels SPX overlapping the curved surfaces LS1ca, LS2ca, LS3ca, . . . may be viewed in an elongated shape.

According to the present embodiment, precise alignment of the lens array LSA and the display panel DP using the individual sub-pixels SPX viewed through the flat surfaces TR12a, TR23a, . . . is possible. In particular, since the precise alignment of the lens array LSA and the display panel DP is possible through a microscope without turning on the display panel DP (the sub-pixels SPX are in a non-emission state), the takt time may be reduced, and thus mass production of the display device 10 is very advantageous.

FIG. 7 is a diagram illustrating a display panel including align marks.

Referring to FIG. 7, the display panel DP′ may further include the alignment marks am overlapping the flat surfaces TR12a, . . . .The alignment marks am may be formed at a position which does not overlap the sub-pixels SPX.

According to the present embodiment, precise alignment of the lens array LSA and the display panel DP′ using the alignment marks am viewed through the flat surfaces TR12a, TR23a, . . .is possible. In particular, since the precise alignment of the lens array LSA and the display panel DP′ is possible through a microscope without turning on the display panel DP′ (the sub-pixels SPX are in a non-emission state), the takt time may be reduced, and thus mass production of the display device 10 is very advantageous.

FIG. 8 is a diagram illustrating a case in which light blockers are formed in the lens array of FIG. 4.

A light blocker BM12a may contact the first side surface LS1s1a of the first lens LS1a, the second side surface LS2s2a of the second lens LS2a, and the flat surface TR12a. To the extent that an element has not been described herein with respect to other light blockers BM01a, BM23a, . . . , it may be assumed that the element is at least similar to corresponding elements that have been described elsewhere within the present disclosure.

The light blockers BM01a, BM12a, BM23a, . . . may be configured of an organic layer including a black dye or a black pigment or a metal layer including an opaque metal material such as chromium (Cr). Crosstalk between different viewpoints may be reduced by the light blockers BM01a, BM12a, BM23a, . . . .

A length of the third direction DR3 of the light blockers BM01a, BM12a, BM23a, . . . may be longer than 6 μm based on the flat surfaces TR01a, TR12a, TR23a, . . . . At this time, transmittance may be less than 0.3%. According to an experimental result, when the length is less than 6 μm, light leakage may occur because light blocking is not sufficient.

Referring back to the description of FIGS. 4 and 5, the first side surfaces LS1s1a, LS2s1a, . . . of the lenses LS1a, LS2a, . . . may be inclined more than 0 degrees and less than 3 degrees in the third direction DR3. Here, the inclined direction may be the direction opposite to the first direction DR1 based on the third direction DR3.

In addition, the second side surfaces LS1s2a, LS2s2a, . . . of the lenses LS1a, LS2a, . . . may be inclined more than 0 degrees and less than 3 degrees with respect to the third direction DR3. Here, the inclined direction may be the first direction DR1 based on the third direction DR3.

Inclinations of the side surfaces determine an inclination of side surfaces of the light blockers BM01a, BM12a, BM23a, . . . . As the inclinations of the side surfaces are closer to 0 degrees, a thin portion of the light blocker BM12a may be eliminated, and thus a light leakage phenomenon may be reduced. When the light leakage phenomenon occurs, a double image may occur, and thus a boundary of an image may be blurred. According to the experimental result, when the inclinations of the side surfaces are less than 3 degrees, the double image is not viewed by a human eye.

FIG. 9 is a diagram illustrating a method of manufacturing a display device according to an embodiment of the disclosure.

Hereinafter, the manufacturing method of FIG. 9 is described with reference to the embodiment of FIGS. 4 and 8.

First, the display panel DP including the plurality of sub-pixels SPX may be prepared. Next, the lens array LSAa, which includes the first lens LS1a including the first curved surface LS1ca and the first side surface LS1s1a connected to one edge of the first curved surface LS1ca, the second lens LS2a including the second curved surface LS2ca and the second side surface LS2s2a connected to one edge of the second curved surface LS2ca, the common lower surface CMBa of the first lens LS1a and the second lens LS2a, and the flat surface TR12a connecting the first side surface LS1s1a and the second side surface LS2s2a and extending parallel to the lower surface CMBa, may be positioned on the display panel DP.

Next, the lens array LSAa and the display panel DP may be aligned using some of the sub-pixels SPX recognized through the flat surfaces TR01a, TR12a, TR23a, . . . (S101). In aligning (S101), the plurality of sub-pixels SPX may be in the non-emission state. For example, even though the display panel DP does not display an image, it is possible to check whether the lens array LSAa and the display panel DP are aligned by observing the sub-pixels SPX through a microscope.

After the lens array LSAa and the display panel DP are aligned, the light blockers BM01a, BM12a, BM23a, . . . may be formed on the flat surfaces TR01a, TR12a, TR23a, . . . (S102). The light blockers BM01a, BM12a, BM23a, . . . may be formed using various processes. For example, the light blockers BM01a, BM12a, BM23a, . . . may be coated on the flat surfaces TR01a, TR12a, TR23a, . . . as a liquid type such as an ink, and then may be cured by ultraviolet rays or heat. For example, the light blockers BM01a, BM12a, BM23a, . . . may have a property similar to that of a gel type of solid. A refractive index of the light blockers BM01a, BM12a, BM23a, . . . may be configured to be less than or equal to a refractive index of the lenses LS1a, LS2a, . . . .

Hereinafter, the manufacturing method of FIG. 9 is described with reference to the embodiment of FIGS. 7 and 8.

First, the display panel DP′ including the plurality of sub-pixels SPX and the plurality of alignment marks am may be prepared. Next, the lens array LSAa, which includes the first lens LS1a including the first curved surface LS1ca and the first side surface LS1s1a connected to one edge of the first curved surface LS1ca, the second lens LS2a including the second curved surface LS2ca and the second side surface LS2s2a connected to one edge of the second curved surface LS2ca, the common lower surface CMBa of the first lens LS1a and the second lens LS2a, and the flat surface TR12a connecting the first side surface LS1s1a and the second side surface LS2s2a and extending parallel to the lower surface CMBa, may be positioned on the display panel DP′.

Next, the lens array LSAa and the display panel DP′ may be aligned using the align marks am recognized through the flat surfaces TR01a, TR12a, TR23a, . . . (S101). In aligning (S101), the plurality of sub-pixels SPX may be in the non-emission state. For example, even though the display panel DP′ does not display an image, it is possible to check whether the lens array LSAa and the display panel DP′ are aligned by observing the align marks am through a microscope.

After the lens array LSAa and the display panel DP′ are aligned, the light blockers BM01a, BM12a, BM23a, . . . may be formed on the flat surfaces TR01a, TR12a, TR23a, . . . (S102). The light blockers BM01a, BM12a, BM23a, . . . may be formed using various processes. For example, the light blockers BM01a, BM12a, BM23a, . . . may be coated on the flat surfaces TR01a, TR12a, TR23a, . . . as a liquid type such as an ink, and then may be cured by ultraviolet rays or heat. For example, the light blockers BM01a, BM12a, BM23a, . . . may have a property similar to that of a gel type of solid. A refractive index of the light blockers BM01a, BM12a, BM23a, . . . may be configured to be less than or equal to a refractive index of the lenses LS1a, LS2a, . . . .

FIGS. 10 to 12 are diagrams illustrating a lens array according to still other embodiments of the disclosure.

Referring to FIG. 10, the lens array LSAb may include lenses LS1b, LS2b, . . . . An overlap relationship between the lenses LS1b, LS2b, . . . and the sub-pixels SPX refers to the description of FIG. 4.

A first lens LS1b may include a first curved surface LS1cb curved in the third direction DR3, a first lower surface LS1bb, a first side surface LS1s1b connected to one edge of the first lower surface LS1bb, and a second side surface LS1s2b connected to another edge of the first lower surface LS1bb. The side surfaces LS1s1b and LS1s2b may have an angle ag1 with respect to the second direction DR2 (refer to FIG. 4). The first curved surface LS1cb may be convex in the third direction DR3.

A second lens LS2b may include a second curved surface LS2cb curved in the third direction DR3, a second lower surface LS2bb, a first side surface LS2s1b connected to one edge of the second lower surface LS2bb, and a second side surface LS2s2b connected to another edge of the second lower surface LS2bb. The side surfaces LS2s1b and LS2s2b may have an angle ag1 with respect to the second direction DR2 (refer to FIG. 4). The second curved surface LS2cb may be convex in the third direction DR3. The lower surfaces LS1bb, LS2bb, . . . may face the light emitting surfaces of the sub-pixels SPX of the display panel DP.

A flat surface TR12b may connect the first side surface LS1s1b of the first lens LS1b and the second side surface LS2s2b of the second lens LS2b. An upper flat surface ft12b may connect the first curved surface LS1cb and the second curved surface LS2cb. The flat surface TR12b and the upper flat surface ft12b may extend parallel to each other.

A length p12b of the first direction DR1 of the flat surface TR12b may be longer than the length of the first direction DR1 of any one of the sub-pixels SPX. Therefore, at least one sub-pixel may be fully viewed based on the first direction DR1 through the flat surface TR12b, and thus alignment using the sub-pixels SPX is possible in a process of aligning the lens array LSAb and the display panel DP.

In an embodiment, the length p12b of the first direction DR1 of the flat surface TR12b may be two or more times longer than the length of the first direction DR1 of any one of the sub-pixels SPX. When the sub-pixels SPX have a PENTILE™ structure, at least one pixel (e.g., a set of adjacent first color pixel, second color pixel, and third color pixel) is fully viewed based on the first direction DR1 through the flat surface TR12b, and thus alignment using the pixels is possible in the alignment process of the lens array LSAb and the display panel DP.

In an embodiment, the length p12b of the first direction DR1 of the flat surface TR12b may be three or more times longer than the length of the first direction DR1 of any one of the sub-pixels SPX. When the sub-pixels SPX have a RGB stripe structure, at least one pixel (e.g., a set of adjacent first color pixel, second color pixel, and third color pixel) is fully viewed based on the first direction DR1 through the flat surface TR12b, and thus alignment using the pixels is possible in the alignment process of the lens array LSAb and the display panel DP.

To the extent that an element has not been described herein with respect to flat surfaces TR01b, TR23b, . . . between other lenses, it may be assumed that the element is at least similar to corresponding elements that have been described elsewhere within the present disclosure.

A length of the first direction DR1 of the first curved surface LS1cb or the second curved surface LS2cb may be longer than the length p12b of the first direction DR1 of the flat surface TR12b. Since the curved surfaces LS1cb, LS2cb, . . . of the lenses LS1b, LS2b, . . . serve as a main function for displaying a stereoscopic image, remaining sub-pixels SPX except for the sub-pixels SPX covered by the flat surfaces TR01b, TR12b, TR23b, . . . are covered.

The first side surfaces LS1s1b, LS2s1b, . . . of the lenses LS1b, LS2b, . . . may be inclined at an angle more than 0 degrees and less than 3 degrees with respect to the third direction DR3. Here, an inclined direction of a first angle ag1b may be a direction opposite to the first direction DR1 based on the third direction DR3.

In addition, the second side surfaces LS1s2b, LS2s2b, . . . of the lenses LS1b, LS2b, . . . may be inclined at an angle more than 0 degrees and less than 3 degrees with respect to the third direction DR3. Here, an inclined direction of a second angle ag2b may be the first direction DR1 based on the third direction DR3.

A light blocker BM12b may contact the first side surface LS1s1b of the first lens LS1b, the second side surface LS2s2b of the second lens LS2b, and the flat surface TR12b. To the extent that an element has not been described herein with respect to other light blockers BM01b, BM23b, . . . , it may be assumed that the element is at least similar to corresponding elements that have been described elsewhere within the present disclosure.

The light blockers BM01b, BM12b, BM23b, . . . may be configured of an organic layer including a black dye or a black pigment or a metal layer including an opaque metal material such as chromium (Cr). Crosstalk between different viewpoints may be reduced by the light blockers BM01b, BM12b, BM23b, . . . .

A length of the third direction DR3 of the light blockers BM01b, BM12b, BM23b, . . . may be longer than 6 μm based on the flat surfaces TR01b, TR12b, TR23b, . . . . At this time, transmittance may be less than 0.3%. According to an experimental result, when the length is less than 6 μm, light leakage may occur because light blocking is not sufficient.

Inclinations of the first side surfaces LS1s1b, LS2s1b, . . . and the second side surfaces LS1s2b, LS2s2b, . . . determine an inclination of side surfaces of the light blockers BM01b, BM12b, BM23b, . . . . As the inclinations of the side surfaces are closer to 0 degrees, a thin portion of the light blocker BM12b may be eliminated, and thus a light leakage phenomenon may be reduced. When the light leakage phenomenon occurs, a double image may occur, and thus a boundary of an image may be blurred. According to the experimental result, when the inclinations of the side surfaces are less than 3 degrees, the double image is not viewed by a human eye.

Referring to FIG. 12, the lens array LSAc may include lenses LS1c, LS2c, LS3c, . . . . The lenses LS1c, LS2c, LS3c, . . . may overlap the sub-pixels SPX in the third direction DR3. The lenses LS1c, LS2c, LS3c, . . . may be arranged so that a long side has an angle ag1 with respect to the second direction DR2. For example, the lenses LS1c, LS2c, LS3c, . . . may be lenticular lenses.

A first lens LS1c may include a first curved surface LS1cc curved in the third direction DR3, a first side surface LS1s1c connected to one edge of the first curved surface LS1cc, and a second side surface connected to another edge of the first curved surface LS1cc. The side surfaces LS1s1c, . . . may have an angle ag1 with respect to the second direction DR2. The first curved surface LS1cc may be concave in the third direction DR3.

A second lens LS2c may include a second curved surface LS2cc curved in the third direction DR3, a first side surface LS2s1c connected to one edge of the second curved surface LS2cc, and a second side surface LS2s2c connected to another edge of the second curved surface LS2cc. The side surfaces LS2s1c and LS2s2c may have an angle ag1 with respect to the second direction DR2. The second curved surface LS2cc may be concave in the third direction DR3.

The first lens LS1c and the second lens LS2c may have a common lower surface CMBc. The lower surface CMBc may be a common component with respect to remaining lenses of the lens array LSAc. In this case, the lenses LS1c, LS2c, LS3c, . . . of the lens array LSAc may be formed as one body. The lower surface CMBc may have a planar shape extending in the first direction DR1 and the second direction DR2. The lower surface CMBc may face the light emitting surfaces of the sub-pixels SPX of the display panel DP.

A flat surface TR12c may connect the first side surface LS1s1c of the first lens LS1c and the second side surface LS2s2c of the second lens LS2c, and may extend parallel to the lower surface CMBc. A length of the first direction of the flat surface TR12c may be longer than a length of the first direction DR1 of any one of the sub-pixels SPX. Therefore, at least one sub-pixel may be fully viewed based on the first direction DR1 through the flat surface TR12c, and thus alignment using the sub-pixels SPX is possible in an alignment process of the lens array LSAc and the display panel DP.

In an embodiment, the length of the first direction DR1 of the flat surface TR12c may be two or more time longer than the length of the first direction DR1 of any one of the sub-pixels SPX. When the sub-pixels SPX have a PENTILE™ structure, at least one pixel (e.g., a set of adjacent first color pixel, second color pixel, and third color pixel) is fully viewed based on the first direction DR1 through the flat surface TR12c, and thus alignment using the pixels is possible in the alignment process of the lens array LSAc and the display panel DP.

In an embodiment, the length of the first direction DR1 of the flat surface TR12c may be three or more times longer than the length of the first direction DR1 of any one of the sub-pixels SPX. When the sub-pixels SPX have a RGB stripe structure, at least one pixel (e.g., a set of adjacent first color pixel, second color pixel, and third color pixel) is fully viewed based on the first direction DR1 through the flat surface TR12c, and thus alignment using the pixels is possible in the alignment process of the lens array LSAc and the display panel DP.

To the extent that an element has not been described in detail with respect to flat surfaces TR23c, . . . between other lenses, it may be assumed that the element is at least similar to corresponding elements that have been described elsewhere within the present disclosure.

A length of the first direction DR1 of the first curved surface LS1cc or the second curved surface LS2cc may be longer than the length of the first direction DR1 of the flat surface TR12c. Since the curved surfaces LS1cc, LS2cc, LS3cc, . . . of the lenses LS1c, LS2c, LS3c, . . . serve as a main function for displaying a stereoscopic image, remaining sub-pixels SPX except for the sub-pixels SPX covered by the flat surfaces TR12c, TR23c, . . . are covered.

The first side surfaces LS1s1c, LS2s1c, . . . of the lenses LS1c, LS2c, LS3c, . . . may be inclined at an angle more than 0 degrees and less than 3 degrees with respect to the third direction DR3. Here, an inclined direction of an angle may be a direction opposite to the first direction DR1 based on the third direction DR3.

In addition, the second side surfaces LS2s2c, LS3s2c, . . . of the lenses LS1c, LS2c, LS3c, . . . may be inclined at an angle more than 0 degrees and less than 3 degrees with respect to the third direction DR3. Here, an inclined direction of an angle may be the first direction DR1 based on the third direction DR3.

A light blocker BM12c may contact the first side surface LS1s1c of the first lens LS1c, the second side surface LS2s2c of the second lens LS2c, and the flat surface TR12c. Since the same description may be applied to other light blockers BM23c, . . . , to the extent that an element has not been described in detail herein, it may be assumed that the element is at least similar to corresponding elements that have been described elsewhere within the present disclosure.

The light blockers BM12c, BM23c, . . .may be configured of an organic layer including a black dye or a black pigment or a metal layer including an opaque metal material such as chromium (Cr). Crosstalk between different viewpoints may be reduced by the light blockers BM12c, BM23c, . . . .

A length of the third direction DR3 of the light blockers BM12c, BM23c, . . . may be longer than 6 μm based on the flat surfaces TR12c, TR23c, . . . . At this time, transmittance may be less than 0.3%. According to an experimental result, when the length is less than 6 μm, light leakage may occur because light blocking is not sufficient.

Inclinations of the side surfaces of the lenses LS1c, LS2, LS3c, . . . determine an inclination of side surfaces of the light blockers BM12c, BM23c, . . . . As the inclinations of the side surfaces are closer to 0 degrees, a thin portion of the light blocker BM12c may be eliminated, and thus a light leakage phenomenon may be reduced. When the light leakage phenomenon occurs, a double image may occur, and thus a boundary of an image may be blurred. According to the experimental result, when the inclinations of the side surfaces are less than 3 degrees, the double image is not viewed by a human eye.

The drawings referred to so far and the detailed description of the disclosure described herein may represent examples of the disclosure, are used for describing the disclosure, and are not necessarily intended to limit the meaning and the scope of the disclosure. Therefore, those skilled in the art will understand that various modifications and equivalent other embodiments are possible from these.

What is claimed is:

1. A display device, comprising:
a display panel including sub-pixels arranged in a first direction and a second direction perpendicular to the first direction, the sub-pixels each including a light emitting surface facing a third direction that is perpendicular to the first direction and the second direction; and
lenses at least partially overlapping the sub-pixels in the third direction, each of the lenses having a long side having an angle greater than 0 degree with respect to the second direction, wherein the lenses comprise:
a first lens including a first curved surface that is curved with respect to the third direction and a first side surface that is connected to one edge of the first curved surface, the first side surface being inclined at a first angle with respect to the third direction;
a second lens including a second curved surface that is curved with respect to the third direction and a second side surface connected to one edge of the second curved surface, the second side surface being inclined at a second angle with respect to the third direction;
a common lower surface of the first lens and the second lens; and
a flat surface connecting the first side surface and the second side surface to each other and extending in parallel to the common lower surface,
wherein a magnitude of each of the first angle and the second angle is greater than 0 degrees.

2. The display device according to claim 1, wherein the magnitude of the first angle is equal to the magnitude of the second angle, and a sign of the first angle is opposite a sign of the second angle.

3. The display device according to claim 1, wherein a length in the first direction of the flat surface is longer than a length in the first direction of any one of the sub-pixels, and
wherein a length in the first direction of the first curved surface or a length in the first direction of the second curved surface is longer than the length in the first direction of the flat surface.

4. The display device according to claim 1, wherein a length in the first direction of the flat surface is at least two times longer than a length in the first direction of any one of the sub-pixels.

5. The display device according to claim 1, wherein a magnitude of each of the first angle and the second angle is less than 3 degrees.

6. The display device according to claim 1, wherein the first curved surface and the second curved surface are convex in the third direction.

7. The display device according to claim 1, wherein the first curved surface and the second curved surface are concave in the third direction.

8. The display device according to claim 1, further comprising:
a light blocker contacting the first side surface, the second side surface, and the flat surface.

9. The display device according to claim 8, wherein a length in the third direction of the light blocker is longer than 6 μm.

10. The display device according to claim 1,
wherein the display panel further comprises align marks at least partially overlapping the flat surface.

11. A method of manufacturing a display device, the method comprising:
preparing a display panel including a plurality of sub-pixels;
positioning a lens array on the display panel, the lens array including a first lens including a first curved surface and a first side surface connected to one edge of the first curved surface, a second lens including a second curved surface and a second side surface connected to one edge of the second curved surface, a common lower surface of the first lens and the second lens, and a flat surface connecting the first side surface and the second side surface to one another and extending parallel to the common lower surface; and
aligning the lens array and the display panel with one another using at least some of the sub-pixels observed through the flat surface.

12. The method according to claim 11, wherein, in the step of aligning, the plurality of sub-pixels are in a non-emission state.

13. The method according to claim 11, further comprising:
forming a light blocker on the flat surface after the lens array and the display panel are aligned.

14. The method according to claim 13, wherein a depth of the light blocker is longer than 6 μm.

15. The method according to claim 11, wherein a width of the flat surface is greater than a width of any one of the sub-pixels.

16. A method of manufacturing a display device, the method comprising:
preparing a display panel including a plurality of sub-pixels and a plurality of alignment marks;
positioning a lens array on the display panel, the lens array including a first lens including a first curved surface and a first side surface connected to one edge of the first curved surface, a second lens including a second curved surface and a second side surface connected to one edge of the second curved surface, a common lower surface of the first lens and the second lens, and a flat surface connecting the first side surface and the second side surface to one another and extending parallel to the common lower surface; and
aligning the lens array and the display panel with one another using the alignment marks observed through the flat surface.

17. The method according to claim 16, wherein, in the step of aligning, the plurality of sub-pixels are in a non-emission state.

18. The method according to claim 16, further comprising:
forming a light blocker on the flat surface after the lens array and the display panel are aligned.

19. The method according to claim 18, wherein a depth of the light blocker is longer than 6 μm.

20. The method according to claim 16, wherein a width of the flat surface is greater than a width of any one of the sub-pixels.
